(19) United States
(12) Patent Application Publication
(10) Pub. No.: US 2014/0141958 A1
(43) Pub. Date: May 22, 2014

(54) SUBSTRATE FOR OLED, METHOD OF FABRICATING THE SAME AND ORGANIC LIGHT-EMITTING DEVICE HAVING THE SAME

(71) Applicant: SAMSUNG CORNING PRECISION MATERIALS CO., LTD., Gumi-si (KR)

(72) Inventors: Kiyeon LEE, Asan-si (KR); JooSok KIM, Asan-si (KR); Jhee-Mann KIM, Asan-si (KR); Seong-Sik PARK, Asan-si (KR); Myeongjin AHN, Asan-si (KR); Jaeho LEE, Asan-si (KR); Eun Young CHO, Asan-si (KR)

(73) Assignee: SAMSUNG CORNING PRECISION MATERIALS CO., LTD., Gumi-si (KR)

(21) Appl. No.: 14/084,268

(22) Filed: Nov. 19, 2013

(30) Foreign Application Priority Data
Nov. 20, 2012 (KR) 10-2012-0131698

(51) Int. Cl. H01L 51/52; C03B 32/02; C03C 4/00

(52) U.S. Cl. CPC H01L 51/5262; C03C 4/0028; C03B 32/02
USPC 501/32; 428/141; 65/33.7

(57) ABSTRACT

A substrate for an organic light-emitting diode (OLED) which can improve the light extraction efficiency of the organic light-emitting device while securing transmittance, a method of fabricating the same, and an organic light-emitting device having the same. The substrate for an OLED is a substrate on which the OLED is to be deposited. The substrate is made of transparent crystallized glass in which a number of crystal grains are distributed.

### CROSS REFERENCE TO RELATED APPLICATION

The present application claims priority from Korean Patent Application Number 10-2012-0131698 filed on Nov. 20, 2012, the entire contents of which are incorporated herein for all purposes by this reference.

### BACKGROUND OF THE INVENTION

1. Field of the Invention

The present invention relates to a substrate for an organic light-emitting diode (OLED), a method of fabricating the same and an organic light-emitting device having the same, and more particularly, to a substrate for an OLED which can improve the light extraction efficiency of the organic light-emitting device while securing transmittance, a method of fabricating the same and an organic light-emitting device having the same.

2. Description of Related Art

In general, an organic light-emitting diode (OLED) includes an anode, a light-emitting layer and a cathode. When a voltage is applied between the anode and the cathode, holes are injected from the anode into a hole injection layer and then migrate from the hole injection layer through a hole transport layer to the organic light-emitting layer, and electrons are injected from the cathode into an electron injection layer and then migrate from the electron injection layer through an electron transport layer to the light-emitting layer. Holes and electrons that are injected into the light-emitting layer recombine with each other in the light-emitting layer, thereby generating excitons. When such excitons transit from the excited state to the ground state, light is emitted.

Organic light-emitting displays including an OLED are divided into a passive matrix type and an active matrix type depending on the mechanism that drives an N*M number of pixels which are arranged in the shape of a matrix.

In an active matrix type, a pixel electrode which defines a light-emitting area and a unit pixel driving circuit which applies a current or voltage to the pixel electrode are positioned in a unit pixel area. The unit pixel driving circuit has at least two thin-film transistors (TFTs) and one capacitor. Due to this configuration, the unit pixel driving circuit can supply a constant current irrespective of the number of pixels, thereby realizing uniform luminance. The active matrix type organic light-emitting display consumes little power, and thus can be advantageously applied to high definition displays and large displays.

When light generated by an OLED having an internal emission efficiency of 100% exits outward through, for example, a transparent conductive film made of indium tin oxide (ITO) and a glass substrate, its efficiency is about 17.5% according to Snell's Law. This decreased efficiency has a great effect on the reduction in the internal and external luminous efficiencies in the organic light-emitting device using the glass substrate. In order to overcome this, the transmittance efficiency is increased by escalating optical light extraction efficiency. Accordingly, a number of methods for increasing the optical light extraction efficiency are underway.

Light extraction techniques of the related art include the technique of treating a surface having a texture structure on a glass plate, the technique of applying microspheres to a glass surface on which ITO is deposited, the technique of applying micro-lenses on the glass surface on which ITO is deposited, the technique of using a mesa structure, the technique of using silica aerogel on ITO and the glass surface, and the like. Among these techniques, the technique of using silica aerogel showed the effect of increasing the quantity of light by 100%. However, silica aerogel is very sensitive to moisture and unstable, thereby resulting in the reduced longevity of a device. Accordingly, it was impossible to commercially use this technique.

In addition, although the technique of using the micro-lenses or mesa structure increased the external light efficiency, fabricating cost was greatly increased. This consequently causes the problem of low practicability. In addition, in the technique of using microspheres, no increase in the external luminous efficiency appeared but only the wavelength was changed due to dispersion of light. Therefore, the method of using the texture structure that has brought the efficiency increase of 30% to the organic light-emitting device is most advantageous in terms of the longevity and cost of the device. However, since glass is amorphous, it is very difficult to form the texture structure having a certain shape on the glass plate. In addition, even if the texture is formed on the glass plate, the flatness is lowered by the texture. Consequently, the texture structure is also formed on the surface of the anode that adjoins to the glass plate, whereby leakage current occurs. This consequently creates many problems in the structure or process. For example, when the texture structure is applied for internal light extraction, an additional planarization film is required.

The information disclosed in the Background of the Invention section is provided only for better understanding of the background of the invention, and should not be taken as an acknowledgment or any form of suggestion that this information forms a prior art that would already be known to a person skilled in the art.

### RELATED ART DOCUMENT

Patent Document 1: Korean Patent Application Publication No. 10-2012-0018165 (Feb. 29, 2012)

### BRIEF SUMMARY OF THE INVENTION

Various aspects of the present invention provide a substrate for an organic light-emitting diode (OLED) (hereinafter referred to as “OLED substrate”) which can improve the light extraction efficiency of the organic light-emitting device while securing transmittance, a method of fabricating the same and an organic light-emitting device having the same.

In an aspect of the present invention, provided is an OLED substrate on which the OLED is to be deposited. The OLED substrate is made of transparent crystallized glass in which a number of crystal grains are distributed.

According to an embodiment of the present invention, the size of the crystal grains may range from 0.01 to 3 μm.

The transparent crystallized glass may contain an amorphous structure in the range from 10 to 25 volume percent.

The transparent crystallized glass may be lithium aluminosilicate glass.

The crystal grains may have a crystalline phase of one selected from the group consisting of cordierite, silica, eucryptite and spodumene.

The surface roughness (R_{RMS}) of the substrate may be 0.01 μm or less.

The visible transmittance of the substrate may be 50% or greater.

In another aspect of the present invention, provided is a method of fabricating a substrate which is made of transparent crystallized glass, and on which an OLED is to be deposited. The method includes heat-treating the transparent crystallized glass that contains a nucleation agent that promotes precipitation of crystal grains having at least one crystalline phase selected from the group consisting of cordierite, silica, eucryptite and spodumene, thereby controlling the size of the crystal grains that are to be precipitated.

According to an embodiment of the present invention, in the method of fabricating a substrate, the transparent crystallized glass may be heat-treated at a temperature ranging from 850 to 1000° C. for 1 to 2 hours.

In a further aspect of the present invention, provided is an organic light-emitting device that includes the above-described substrate as a light extraction substrate.

According to embodiments of the present invention, it is possible to improve the light extraction efficiency while securing transmittance by controlling the size of crystal grains distributed inside transparent crystallized glass by adjusting the heat treatment condition.

In addition, since the entire OLED substrate made of transparent crystallized glass having high surface flatness acts as not only an external light extraction layer but also an inner light extraction layer of an organic light-emitting device, it is possible to more simplify the structure than a related-art organic light-emitting device in which an external light extraction layer and an internal light extraction layer are formed on both surfaces of a glass substrate. Accordingly, it is possible to realize structural firmness and preclude the external and internal light extraction layers and the planarization film that were formed separate from the glass substrate, thereby simplifying fabrication process and reducing fabrication cost.

Furthermore, when the OLED substrate made of transparent crystallized glass is applied for a light extraction substrate of an organic light-emitting device, it is possible to reduce power consumption of the organic light-emitting device through the improved light extraction efficiency of the organic light-emitting device. This can consequently minimize heat generation, thereby increasing the longevity of the organic light-emitting device.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a cross-sectional view showing an organic light-emitting diode (OLED) substrate according to an embodiment of the present invention;

FIG. 2 is an X-ray diffraction (XRD) graph on the OLED substrate according to an embodiment of the present invention;

FIG. 3 shows pictures comparing the degree of light extraction depending on the heat treatment temperature in a method of fabricating an OLED substrate according to an embodiment of the present invention;

FIG. 4 is a graph showing variations in the wavelength-specific transmittance depending on the heat treatment temperature in the method of fabricating an OLED substrate according to an embodiment of the present invention; and

FIG. 5 shows pictures comparing the degree of light emission of an organic light-emitting device having an OLED substrate that is fabricated by a method of fabricating an OLED substrate according to an embodiment of the present invention as a light extraction substrate with that of an organic light-emitting device having a common amorphous glass.

### DETAILED DESCRIPTION OF THE INVENTION

Reference will now be made in detail to an OLED substrate, a method of fabricating the OLED substrate and an organic light-emitting device having the OLED substrate according to the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

As shown in FIG. 1, the OLED substrate 100 according to an embodiment of the present invention is one of substrates which face each other to encapsulate the OLED, the one substrate being bonded to one surface of the OLED. The OLED substrate 100 protects the OLED from external environment and acts as a path which allows light generated by the OLED to pass outward. According to an embodiment of the present invention, the entire OLED substrate 100 can be applied for a light extraction layer which improves the light extraction efficiency of the organic light-emitting device. Here, since the surface of the OLED substrate 100 has a high level of flatness, the OLED substrate 100 has the function of both internal and external light extraction layers which are separate layers in the related art.

Although not shown, the OLED has a multilayer structure which includes an anode, an organic light-emitting layer and a cathode which are disposed between the substrate 100 according to an embodiment of the present invention and an encapsulation substrate which faces the substrate 100. Here, the anode can be made of a metal or oxide, such as Au, In, Sn or indium tin oxide (ITO), that has a high work function in order to facilitate hole injection, whereas the cathode can be implemented as a thin metal film of Al, Al:Li or Mg:Ag that has a low work function in order to facilitate electron injection. In the case of a top emission structure, the cathode can have a multilayer structure that includes a semitransparent electrode of a thin metal film of Al, Al:Li or Mg:Ag and a transparent electrode of a thin oxide film of ITO in order to facilitate the transmission of light generated by the organic light-emitting layer. In addition, the organic light-emitting layer includes a hole injection layer, a hole transport layer, an emissive layer, an electron transport layer and an electron injection layer which are sequentially stacked on the anode. When a forward voltage is applied between the anode and the cathode, electrons from the cathode migrate to the emissive layer through the electron injection layer and the electron transport layer, while holes from the anode migrate to the emissive layer through the hole injection layer and the hole transport layer. The electrons and holes that have migrated into the emissive layer recombine, thereby generating excitons. When such excitons transit from the excited state to the ground state, light is emitted. The brightness of light that is emitted as such is proportional to the amount of current that flows between the anode and the cathode.

As described above, the OLED substrate 100 is made of glass. According to an embodiment of the present invention, the glass of the OLED substrate 100 is transparent crystallized glass in which a number of crystal grains 110 are distributed. The crystal grains 110 are formed by adding a nucleation agent that promotes precipitation of the crystal grains 110 into mother glass, followed by heat treatment. For example, according to an embodiment of the present invention, as shown in the X-ray diffraction (XRD) graph in FIG. 2, the mother glass can be implemented as lithium aluminosilicate glass. In addition, according to an embodiment of the present invention, the OLED substrate 100 can be implemented as lithium aluminosilicate glass in which two phases of eucryptite and spodumene coexist as the crystal grains 110. The crystal grains 110 of the OLED substrate 100 can be crystal phases that are not only the eucryptite and spodumene but also cordierite or silica.

In this fashion, according to an embodiment of the present invention, the OLED substrate 100 has a structure in which an amorphous structure and a crystalline structure are mixed. Here, according to an embodiment of the present invention, the transparent crystallized glass of the OLED substrate 100 can include an amorphous structure in the range approximately from 10 to 25 volume percent. When the ratio of the amorphous structure in the transparent crystallized glass is less than 10 volume percent, a target transmittance is not obtained although light extraction efficiency is increased. In contrast, when the ratio of the amorphous structure in the transparent crystallized glass exceeds 25 volume percent, the target light extraction efficiency cannot be obtained although transmittance can be obtained. Thus, the ratio of the amorphous structure ranging from 10 to 25 volume percent in the transparent crystallized glass becomes the requirement for obtaining both light extraction efficiency and transmittance that are intended. According to an embodiment of the present invention, the target visible transmittance is 50% or more, and the target light extraction efficiency is 80 cd/m² or more at all viewing angles when converted into luminance.

The crystal grains 110 obstructs the waveguiding phenomenon of light in the substrate 100 by refracting light inside the substrate 100, thereby serving to improve the light extraction efficiency of the organic light-emitting device. This can reduce the power consumption of the organic light-emitting device, thereby minimizing heat generation and ultimately increasing the longevity of the organic light-emitting device.

Here, it is preferred that the crystal grains 110 be randomly distributed in order to increase the refraction of light inside the substrate 100, i.e. in order to vary the direction of light that is emitted. When the direction of light is varied by the randomly-distributed crystal grains 110, color mixing is induced, thereby minimizing the occurrence of a color shift. In addition, it is preferred that the size of the crystal grains 110 range from 0.01 to 3 μm in order to realize a clear image without decreasing the definition of a display device which employs the OLED. When the size of the crystal grains 110 is smaller than 0.01 μm, light extraction efficiency decreases since light scattering effect becomes insignificant. When the size of the crystal grains 110 is greater than 3 μm, light efficiency involving straight propagation decreases due to the decreased transmittance.

As in this embodiment of the present invention, when the size of the crystal grains 110 ranges from 0.01 to 3 μm, it is possible to improve the light extraction efficiency of the organic light-emitting device through light scattering while increasing the visible transmittance of the OLED substrate 100 to, for example, 50% or more.

According to an embodiment of the present invention, the OLED substrate 100 has a surface roughness (R_{RMS}) of 0.01 μm or less. Since the surface of the OLED substrate 100 has high flatness, a planarization film that was used when a related-art light extraction layer having a concave-convex structure was applied for an internal light extraction layer can be precluded. In addition, the OLED substrate 100 serves as the internal light extraction layer, the glass substrate and the external light extraction layer of the related art. Since the OLED substrate 100 has high surface flatness, the shape of the anode of the OLED is maintained even though the OLED substrate 100 contacts the anode. It is therefore possible to fundamentally prevent the related-art problems, such as leak current, caused by the shape change of the anode depending on the shape of the light extraction layer. In addition, when the OLED substrate 100 is applied for the light extraction layer of the organic light-emitting device, the internal light extraction layer and the external light extraction layer that were formed as separate layers on the front and rear surfaces of the glass substrate in the related art can be precluded either. Therefore, compared to the related art, it is possible to increase structural firmness, more simplify the fabrication process, and reduce fabrication cost.

Reference will now be made of a method of fabricating an OLED substrate according to an embodiment of the present invention.

The method of fabricating an OLED substrate includes, first, preparing mother glass in which a nucleation agent is added. The mother glass can be implemented as lithium aluminosilicate glass. The nucleation agent added to the mother glass precipitates crystal grains (110 in FIG. 1) that are crystals of at least one selected from among cordierite, silica, eucryptite and spodumene.

Afterwards, the mother glass containing the nucleation agent is heat-treated so that the crystal grains (110 in FIG. 1) precipitate, thereby producing transparent crystallized glass. The size of the crystal grains (110 in FIG. 1) that are to precipitate is controlled by adjustment of heat treatment temperature and time.

Specifically, the mother glass containing the nucleation agent is heat-treated at a temperature ranging from 850 to 1000° C. for 1 to 2 hours. When the mother glass is heat-treated under these heat treatment conditions, the OLED substrate (100 in FIG. 1) made of transparent crystallized glass is fabricated. In the transparent crystallized glass, the size of the crystal grains (110 in FIG. 1) ranges from 0.01 to 3 μm, the surface roughness (R_{RMS}) is 0.01 μm or less, and the visible transmittance is 50% or more.

Here, the crystallinity of the mother glass that contains the nucleation agent is 84%, and the crystallinity of the transparent crystallized glass produced after heat treatment ranges from 84 to 89%. As the crystal grains (110 in FIG. 1) precipitate due to the heat treatment, the ratio of the amorphous structure inside the glass gradually decreases.

### Example 1

Transparent crystallized glass was fabricated by heat-treating lithium aluminosilicate glass that contains a nucleation agent at 850° C. for 1 hour. The transmittance, reflectance and crystallinity of the fabricated transparent crystallized glass were measured. The maximum visible transmittance was 87.6%, the reflectance was 8.43%, and the crystallinity was 84%.

### Example 2

Transparent crystallized glass was fabricated by heat-treating glass that has the same composition as in Example 1 at 850° C. for 2 hour. The transmittance, reflectance and crystallinity of the fabricated transparent crystallized glass were measured. The maximum visible transmittance was 87.9%, the reflectance was 8.43%, and the crystallinity was 87%.

### Example 3

Transparent crystallized glass was fabricated by heat-treating glass that has the same composition as in Example 1 at 900° C. for 1 hour. The transmittance, reflectance and crystallinity of the fabricated transparent crystallized glass were measured. The maximum visible transmittance was 83.6%, the reflectance was 9.06%, and the crystallinity was 88%.

### Example 4

Transparent crystallized glass was fabricated by heat-treating glass that has the same composition as in Example 1 at 1000° C. for 1 hour. The transmittance, reflectance and crystallinity of the fabricated transparent crystallized glass were measured. The maximum visible transmittance was 60.5%, the reflectance was 24.07%, and the crystallinity was 89%.

### Comparative Example 1

The transmittance, reflectance and crystallinity of glass that has the same composition as in Example 1 were measured before heat treatment. The maximum visible transmittance was 87.6%, the reflectance was 8.0%, and the crystallinity was 84%.

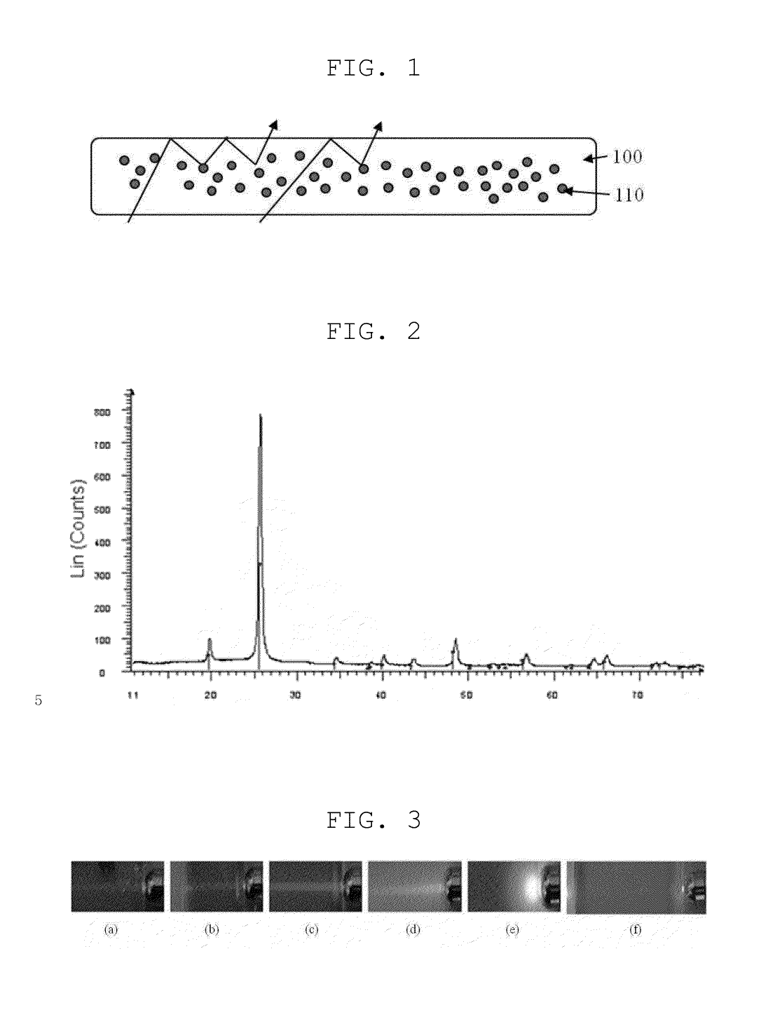

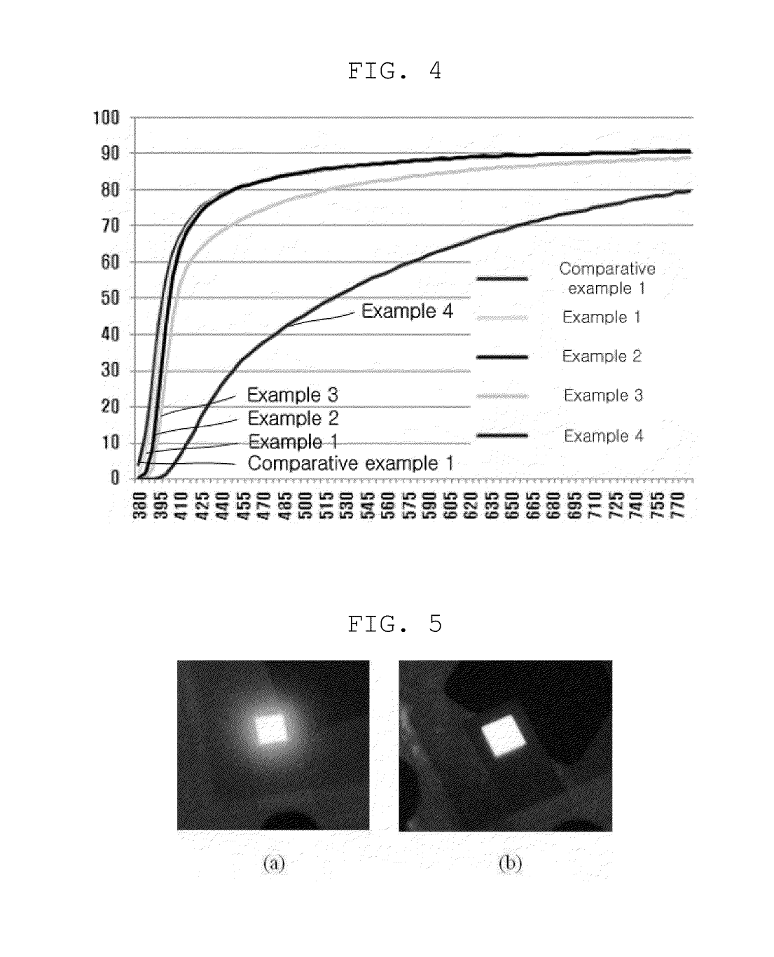

FIG. 3 shows pictures in which the degree of light extraction is compared among Example 1 to Example 4, Comparative Example 1 and common amorphous glass. Here, (a) is the picture of light extraction from Comparative Example 1, (b) to (e) are pictures of light extraction from Example 1 to Example 4, and (f) is the picture of light extraction from the common amorphous glass. First, comparing the picture (f) with the pictures (a) to (e), it can be appreciated that the degree of light extraction of lithium aluminosilicate glass that contains the nucleation agent is greater than that of the common amorphous glass. In addition, comparing Comparative Example 1 in the picture (a) that was not heat-treated with Example 1 to Example 4 in the pictures (b) to (e) that were heat-treated, it can be visually appreciated that the degree of light extraction was increased after the heat treatment. In addition, it can be appreciated that the degree of light extraction increased with the increasing heat treatment time at the same heat treatment temperature. The degree of light extraction was maximized when heat treated at 900° C. for 1 hour as in Example 3 (the picture (d)).

FIG. 4 is a graph showing variations in the wavelength-specific transmittance of Example 1 to Example 4 and Comparative Example 4. Referring to the graph in FIG. 4, it is noticeable that the relative transmittance of Example 2 (the picture (c) in FIG. 3) is greatest. It is also noticed that, in the cases (the pictures (d) and (e) in FIG. 3) where the heat treatment temperature was higher than that in Example 2 (the picture (c) in FIG. 3), the transmittance decreased than before the heat treatment (the picture (a) in FIG. 3).

It is preferred that the heat treatment temperature be raised in order to improve light extraction efficiency. However, the crystallinity tends to increase with the rising heat treatment temperature, thereby decreasing the transmittance. Accordingly, it is appreciated that the heat treatment temperature is preferably 1000° C. or below in order to ensure the visible transmittance of 50% or greater.

TABLE 1

| Viewing | | Common | Comp. | | | | |
|---|---|---|---|---|---|---|---|
| angle | LGP¹⁾ | glass | Ex. 1 | Ex. 1 | Ex. 2 | Ex. 3 | Ex. 4 |
| 0 | 19 | 28 | 73 | 81 | 230 | 3,001 | 9,286 |
| 10 | 19 | 28 | 74 | 82 | 232 | 3,012 | 9,311 |
| 20 | 19 | 31 | 75 | 83 | 237 | 3,064 | 9,430 |
| 30 | 22 | 34 | 79 | 86 | 247 | 3,153 | 9,609 |
| 40 | 27 | 37 | 87 | 93 | 259 | 3,270 | 9,873 |
| 50 | 33 | 44 | 101 | 106 | 279 | 3,411 | 10,170 |
| 60 | 49 | 59 | 125 | 131 | 311 | 3,571 | 10,390 |
| 70 | 78 | 91 | 314 | 214 | 383 | 3,768 | 10,390 |

Note)
LGP¹⁾lightguide plate

Table 1 above presents luminance values depending on changes in the viewing angle that were measured by placing a piece of common amorphous glass, a piece of glass according to Comparative Example 1 and pieces of glass according to Example 1 to Example 4 on a light guide plate in order to examine the degree of improvement in the light extraction efficiency of the pieces of glass according to examples. Referring to Table 1, it is noticeable that the same results as in FIG. 3 were measured in luminance values. Over the entire viewing angles, Example 1 to Example 4 were measured to have a higher luminance value than Comparative Example 1. It is noticeable that the luminance increased with the increasing heat treatment temperature. In particular, Example 4 was measured to have predominantly high luminance values over the entire viewing angles. This means that the light extraction efficiency of Example 4 is greatest.

In addition, the power consumption of the organic light-emitting device in which a substrate (100 in FIG. 1) according to an embodiment of the present invention is applied for a light extraction layer and the power consumption of an organic light-emitting device in which a piece of common amorphous glass is applied were measured. The measurements present that the power consumption of the organic light-emitting device in which the substrate (100 in FIG. 1) according to an embodiment of the present invention is applied for a light extraction layer was reduced by about 40% or more. When the power consumption is reduced as such, the heat generation of the organic light-emitting device is minimized, and thus the longevity of the organic light-emitting device can be increased.

FIG. 5 shows pictures comparing the degree of light emission of an organic light-emitting device (a) having an OLED substrate that is fabricated by a method of fabricating an OLED substrate according to an embodiment of the present invention as a light extraction substrate with that of an organic light-emitting device (b) having a common amorphous glass. It can be visually noticed that the organic light-emitting device (a) is predominantly brighter than the organic light-emitting device (b). This means that the light extraction efficiency was improved by the OLED substrate (100 in FIG. 1) according to an embodiment of the present invention.

The foregoing descriptions of specific exemplary embodiments of the present invention have been presented with respect to the drawings. They are not intended to be exhaustive or to limit the present invention to the precise forms disclosed, and obviously many modifications and variations are possible for a person having ordinary skill in the art in light of the above teachings.

It is intended therefore that the scope of the present invention not be limited to the foregoing embodiments, but be defined by the Claims appended hereto and their equivalents.

What is claimed is:

1. A substrate on which an organic light-emitting diode is to be deposited, comprising transparent crystallized glass in which a number of crystal grains are distributed.

2. The substrate of claim 1, wherein a size of the crystal grains ranges from 0.01 to 3 μm.

3. The substrate of claim 1, wherein the transparent crystallized glass comprises an amorphous structure in a range from 10 to 25 volume percent.

4. The substrate of claim 1, wherein the transparent crystallized glass comprises lithium aluminosilicate glass.

5. The substrate of claim 4, wherein the crystal grains comprise a crystalline phase of one selected from the group consisting of cordierite, silica, eucryptite and spodumene.

6. The substrate of claim 1, wherein a surface roughness (R_{RMS}) of the substrate is 0.01 μm or less.

7. The substrate of claim 1, wherein a visible transmittance of the substrate is 50% or greater.

8. A method of fabricating a substrate which comprises transparent crystallized glass, and on which an organic light-emitting diode is to be deposited, the method comprising heat-treating the transparent crystallized glass that contains a nucleation agent that promotes precipitation of crystal grains, thereby controlling a size of the crystal grains that are to be precipitated.

9. The method of claim 8, wherein heat-treating the transparent crystallized glass comprises heat-treating the transparent crystallized glass at a temperature ranging from 850 to 1000° C. for 1 to 2 hours.

10. The substrate of claim 8, wherein the crystal grains comprise a crystalline phase of one selected from the group consisting of cordierite, silica, eucryptite and spodumene.

11. An organic light-emitting device comprising the substrate recited in claim 1 as a light extraction substrate.
